(19) United States
(12) Patent Application Publication
(10) Pub. No.: US 2024/0146035 A1
(43) Pub. Date: May 2, 2024

(54) SEMICONDUCTOR LASER DEVICE

(71) Applicant: Ushio Denki Kabushiki Kaisha, Tokyo (JP)

(72) Inventor: Seiji KITAMURA, Tokyo (JP)

(73) Assignee: Ushio Denki Kabushiki Kaisha, Tokyo (JP)

(21) Appl. No.: 18/495,415

(22) Filed: Oct. 26, 2023

(30) Foreign Application Priority Data
Oct. 27, 2022 (JP) 2022-172711

(51) Int. Cl. H01S 5/40

(52) U.S. Cl. CPC H01S 5/4087; H01S 5/4031

(57) ABSTRACT

A semiconductor laser device includes an edge-emitting type first semiconductor laser element having a relatively short oscillation wavelength at a room temperature, and an edge-emitting type second semiconductor laser element having a relatively long oscillation wavelength at the room temperature. A difference in the oscillation wavelength at the room temperature between the first semiconductor laser element and the second semiconductor laser element is 20 nm or less. At least one of a film thickness, a refractive index, and a number of layers is different between reflective films on emitting edges of the first semiconductor laser element and the second semiconductor laser element. An emitting side reflectance of the first semiconductor laser element at an operating temperature upper limit is higher than an emitting side reflectance of the second semiconductor laser element at the operating temperature upper limit.

### BACKGROUND

### 1. Technical Field

The present disclosure relates to a semiconductor laser device.

### 2. Description of the Related Art

In recent years, devices using semiconductor lasers are strongly required to be stably usable in a wide temperature range. Generally, a semiconductor laser element has characteristics in that a threshold current increases as an operating temperature rises. The increase in threshold current is caused by a phenomenon (carrier overflow) in which electrons in a high energy state overflow a cladding layer. (JP 2006-049420 A).

Temperature dependency of the threshold current is expressed by the following equation by using a characteristic temperature T₀.

I=I₀×exp(T/T₀)

A characteristic temperature T₀ of a red laser having a wavelength of 640 nm is about 80 K, and a characteristic temperature of a laser having a wavelength of 780 nm is about 150 K.

The increase in the threshold current at a high temperature is almost dependent on a band gap difference ΔEc between an active layer and a cladding layer. In particular, in the red laser having the wavelength of 640 nm, ΔEc is small due to limitation of a constituent material, and the increase in the threshold current with the temperature rise becomes remarkable. As a result, there is a problem that an increase in an operating current is caused, heat generation is increased, and a remaining lifespan is shortened.

In addition, the temperature dependency of the threshold current causes the following problems in a device in which a plurality of semiconductor laser elements are mounted. In such a device, oscillation wavelengths of the plurality of semiconductor laser elements have manufacturing variations for each semiconductor laser element, but the semiconductor laser element having a short oscillation wavelength has a large increase in threshold current with temperature rise, and the semiconductor laser element having a long oscillation wavelength has a smaller increase in threshold current with temperature rise than the semiconductor laser element having the short oscillation wavelength. Thus, when the plurality of semiconductor laser elements are driven with the same amount of current, a light output difference between the semiconductor laser elements increases.

The operating current at a high temperature is desirably close to the threshold current, and smaller as compared with those at a room temperature and a low temperature. This is because a light output is saturated even though the operating current is increased at the high temperature, and the remaining lifespan is shortened as the operating current increases. Thus, the reduction of a variation in the threshold current is more effective in reducing a variation in the light output than the reduction of a variation in slope efficiency.

A method for increasing a reflectance of an emitting edge (referred to as an emitting side reflectance) is known as a method for reducing the threshold current in a high temperature operation. According to this method, a light density inside the laser is increased, and the threshold current at the high temperature can be lowered. On the other hand, when the laser emission end reflectance is increased, since a high light output is required in an operation at the low temperature and the room temperature, there is a problem that the light density near the emitting edge is increased, and damage (COD: Catastrophic Optical Damage) is likely to occur.

In order to solve this problem, a method in which wavelength dependency is imparted to the emission end reflectance and the emission end reflectance is increased as the wavelength becomes longer has been proposed (JP 07-74427 A). Generally, the semiconductor laser has characteristics in that an oscillation wavelength shifts to a long wavelength as a temperature rises. By using such characteristics, light confinement at the high temperature can be increased and the increase in threshold current at the high temperature can be reduced by increasing the emission end reflectance as the wavelength becomes longer (=high temperature operation).

On the other hand, since the oscillation wavelength in the operation at the low temperature and the room temperature is shorter than that in the operation at the high temperature, the emission end reflectance is suppressed, and high COD resistance can be obtained.

The present inventors have recognized that the following problems occur in a case where the technology described in Patent document JP07-74427 A is applied to a device on which a plurality of semiconductor laser elements are mounted.

Comparing a semiconductor laser element having a short oscillation wavelength and a semiconductor laser element having a long oscillation wavelength, since a shift width of the long oscillation wavelength of these devices translates in the operation from the room temperature to the high temperature, a difference in increase rate of the threshold current at the high temperature does not decrease, and as a result, the problem of the light output difference cannot be solved.

### SUMMARY

The present disclosure has been made in such a situation, and one illustrative object thereof is to provide a semiconductor laser device in which a variation in the threshold current at a high temperature is reduced.

A semiconductor laser device according to an aspect of the present disclosure includes an edge-emitting type first semiconductor laser element having a relatively short oscillation wavelength at a room temperature, and an edge-emitting type second semiconductor laser element having a relatively long oscillation wavelength at the room temperature. A difference in the oscillation wavelength at the room temperature between the first semiconductor laser element and the second semiconductor laser element is 20 nm or less, and at least one of a film thickness, a refractive index, and a number of layers is different between a reflective film on an emitting edge of the first semiconductor laser element and a reflective film on an emitting edge of the second semiconductor laser element. An emitting side reflectance of the first semiconductor laser element at an operating temperature upper limit is higher than an emitting side reflectance of the second semiconductor laser element at the operating temperature upper limit.

Another aspect of the present disclosure is also a semiconductor laser device. The semiconductor laser device includes a plurality of semiconductor laser elements having different oscillation wavelengths at a room temperature. At least one of a film thickness, a refractive index, a number of layers is different between reflective films on emitting edges of the plurality of semiconductor laser elements. As statistically viewed, an emitting side reflectance of the semiconductor laser element having a short oscillation wavelength at an operating temperature upper limit at the room temperature is higher than an emitting side reflectance of the semiconductor laser element having a long oscillation wavelength at the operating temperature upper limit at the room temperature.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram illustrating a semiconductor laser device according to a first embodiment;

FIG. 2 is a diagram illustrating wavelength dependencies of emitting side reflectances R of a short-wavelength element and a long-wavelength element according to Comparative Technology 1;

FIG. 3 is a diagram illustrating I-L (current-light output) characteristics of the semiconductor laser device having the reflectance R in FIG. 2;

FIG. 4 is a diagram illustrating wavelength dependencies of emitting side reflectances R of a short-wavelength element and a long-wavelength element according to Comparative Technology 2;

FIG. 5 is a diagram illustrating I-L characteristics of the semiconductor laser device having the reflectance R in FIG. 4;

FIG. 6 is a diagram illustrating wavelength dependencies of an emission end reflectance RS of a short-wavelength element and an emitting side reflectance RL of a long-wavelength element according to a first embodiment;

FIG. 7 is a diagram illustrating I-L characteristics of the semiconductor laser element having the reflectance characteristics of FIG. 6;

FIG. 8 is a diagram illustrating a wafer;

FIG. 9 is a diagram illustrating wavelength dependencies of an emission end reflectance RS of a short-wavelength element and an emitting side reflectance RL of a long-wavelength element according to a second embodiment;

FIG. 10 is a diagram illustrating a semiconductor laser device according to a modification; and

FIG. 11 is a perspective view of a semiconductor laser package.

### DETAILED DESCRIPTION

### Outline of Embodiments

An outline of some illustrative embodiments of the present disclosure will be described. This outline describes some concepts of one or a plurality of embodiments in a simplified manner for the purpose of basic understanding of the embodiment as an introduction of detailed description to be described below, and does not limit the breadth of the invention or disclosure. In addition, this outline is not a comprehensive outline of all considerable embodiments and does not limit essential components of the embodiments. For the sake of convenience, “one embodiment” may be used to refer to one embodiment (example or modification) or a plurality of embodiments (examples or modifications) disclosed in the present specification.

A semiconductor laser device according to one embodiment includes an edge-emitting type first semiconductor laser element having a relatively short oscillation wavelength at a room temperature, and an edge-emitting type second semiconductor laser element having a relatively long oscillation wavelength at the room temperature. A difference in the oscillation wavelength between the first semiconductor laser element and the second semiconductor laser element at the room temperature is 20 nm or less. At least one of a film thickness, a refractive index, and the number of layers is deferent between a reflective film on an emitting edge of the first semiconductor laser element and a reflective film on an emitting edge of the second semiconductor laser element, and an emitting side reflectance at an upper limit of an operating temperature of the first semiconductor laser element is higher than an emitting side reflectance at an upper limit of an operating temperature of the second semiconductor laser element.

According to this configuration, a difference in the threshold current between the first semiconductor laser element and the second semiconductor laser element at a high temperature can be reduced.

In one embodiment, the plurality of semiconductor laser elements may be cut out from the same wafer. In this case, the plurality of semiconductor laser elements have variations in oscillation wavelength at the room temperature due to process variations. The oscillation wavelengths of the plurality of semiconductor laser elements depend on positions on the wafer before being cut out. Accordingly, a reflective film having a relatively high emitting side reflectance in a high temperature state may be formed in an element positioned in a region on the wafer where the oscillation wavelength tends to be short, and a reflective film having a relatively low emitting side reflectance in the high temperature state may be formed in an element positioned in a region on the wafer where the oscillation wavelength tends to be long.

The semiconductor laser device according to one embodiment may include three or more semiconductor laser elements. The first semiconductor laser element may be an element having a shortest oscillation wavelength at the room temperature among the plurality of semiconductor laser elements, and the second semiconductor laser element may be an element having a longest oscillation wavelength at the room temperature among the plurality of semiconductor laser elements.

In one embodiment, the oscillation wavelength may be between 600 nm and 700 nm. A semiconductor laser element in which an active layer is made of an AlGaInP-based material has particularly poor temperature characteristics. Accordingly, a technology according to the present disclosure is applied to the semiconductor laser element having this oscillation wavelength, and thus, an effect becomes remarkable.

In one embodiment, as the wavelength is longer, the emitting side reflectance of the first semiconductor laser element may be higher. In other words, in one embodiment, the emitting side reflectance of the first semiconductor laser element at the room temperature may be lower than the emitting side reflectance at the upper limit of the operating temperature. Since the light output is usually higher at the room temperature, it is important that a COD resistance at the room temperature is high. On the other hand, in the high temperature state, it can be said that reduction in the threshold current is more important in order to suppress the reduction in the light output. In consideration of balance, it is possible to lower the threshold current at a high temperature while improving the COD resistance by lowering the emitting side reflectance at the room temperature and increasing the emission side reflectance at a high temperature.

In one embodiment, a difference between the emitting side reflectance of the first semiconductor laser element at the room temperature and the emitting side reflectance of the second semiconductor laser element at the room temperature is smaller than a difference between the emitting side reflectance of the first semiconductor laser element at the operating temperature upper limit and the emitting side reflectance of the second semiconductor laser element at the operating temperature upper limit. Since the difference in the light emitting side reflectance at the room temperature affects the difference in the COD resistance, the difference in the emitting side reflectance at the room temperature between the semiconductor laser element having the short wavelength and the semiconductor laser element having the long wavelength is desirably as small as possible. In addition, when the semiconductor laser element having the short wavelength is compared with the semiconductor laser element having the long wavelength, since the variation in the threshold current at the room temperature is smaller than the variation in the threshold current at the high temperature, the difference in the emitting side reflectance at the high temperature between the semiconductor laser element having the short wavelength and the semiconductor laser element having the long wavelength may be large.

In one embodiment, in a graph in which a horizontal axis is plotted as the oscillation wavelength and a vertical axis is plotted as the emitting side reflectance, a slope of the graph of the first semiconductor laser element is larger than a slope of the graph of the second semiconductor laser element. The semiconductor laser element having the short wavelength has a larger increase rate of a wavelength with respect to a temperature change than the semiconductor laser element having the long wavelength. Therefore, the slope of the semiconductor laser element having the long wavelength is set to be larger than the slope of the semiconductor laser element having the short wavelength, and thus, it is possible to reduce the variation in the threshold current between the semiconductor laser element having the short wavelength and the semiconductor laser element having the long wavelength in a wide temperature range.

A semiconductor laser device according to one embodiment includes a plurality of semiconductor laser elements having different oscillation wavelengths at a room temperature. At least one of a film thickness, a refractive index, a number of layers is different between reflective films on emitting edges of the plurality of semiconductor laser elements, and as statistically viewed, an emitting side reflectance of the semiconductor laser element having a short oscillation wavelength at an operating temperature upper limit at the room temperature is higher than an emitting side reflectance of the semiconductor laser element having a long oscillation wavelength at the operating temperature upper limit at the room temperature.

### EMBODIMENTS

Hereinafter, preferred embodiments of the present disclosure will be described with reference to the drawings. The same or equivalent components, members, and processing illustrated in the drawings are denoted by the same reference signs, and the redundant description will be omitted as appropriate. In addition, the embodiments are not intended to limit the disclosure but are examples, and all features described in the embodiments and combinations thereof are not necessarily essential to the disclosure.

Dimensions (thickness, length, width, and the like) of each member described in the drawings may be appropriately enlarged and reduced for easy understanding. Further, dimensions of the plurality of members do not necessarily indicate a magnitude relationship therebetween, and even though a certain member A is drawn thicker than another member B in the drawing, the member A may be thinner than the member B.

### First Embodiment

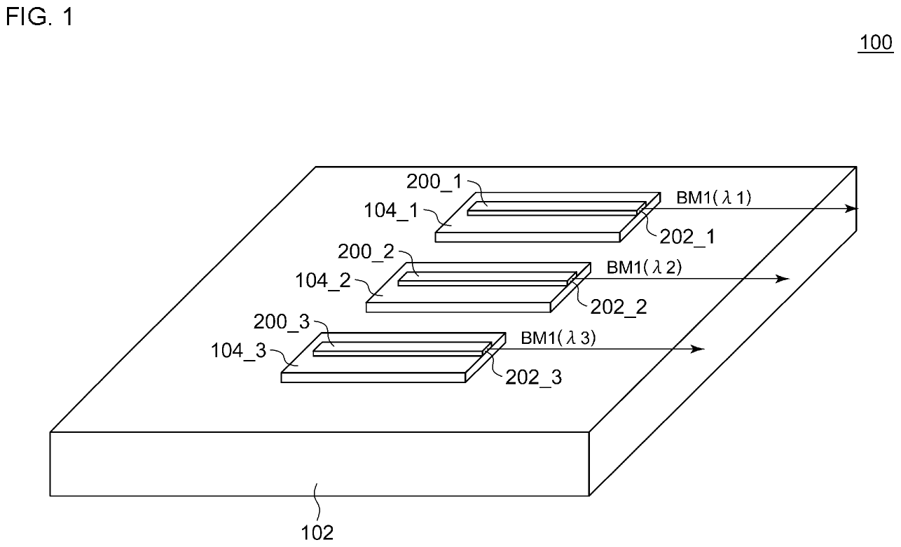

FIG. 1 is a diagram illustrating a semiconductor laser device 100 according to a first embodiment. The semiconductor laser device 100 includes a plurality of semiconductor laser elements 200_1 to 200_N, a heat sink 102, and a plurality of submounts 104_1 to 104_N. In the present embodiment, N=3.

The semiconductor laser elements 200_1 to 200_N are edge-emitting type lasers, and are mounted adjacent to each other on the heat sink 102. An emission color of the semiconductor laser element 200 is not particularly limited, and may be, for example, a red laser having a wavelength of 600 nm to 700 nm.

Each of the semiconductor laser elements 200 is mounted on the submount 104, and the submount 104 is mounted on the heat sink 102. The submount 104 is also referred to as an interposer.

The semiconductor laser element 200 includes a laser resonator formed on a semiconductor substrate. A type and a structure of the laser resonator are not particularly limited, and various known technologies or structures available in the future can be employed.

In order to extract light from an inside of the resonator, a reflective film (emitting edge reflective film) 202_i having a reflectance lower than 100% is formed on an emitting edge of the semiconductor laser element 200_i (i=1 to N).

Although the plurality of semiconductor laser elements 200_1 to 200_N are lasers of the same color manufactured by the same manufacturing process, oscillation wavelengths λ₁ to λ_{N} thereof are different depending on manufacturing variations. It can be said that the order of lengths of the oscillation wavelengths λ₁ to λ₃ is randomly determined because of manufacturing variations.

Here, two elements are selected from among the semiconductor laser elements 200_1 to 200_N are selected, one element of which has a shorter oscillation wavelength λ at a room temperature is referred to as a short-wavelength element 200S, and the other element of which has a longer oscillation wavelength λ at the room temperature is referred to as a long-wavelength element 200L.

In the semiconductor laser device 100 including N=three or more semiconductor laser elements, for example, the short-wavelength element 200S may be an element having a shortest oscillation wavelength at the room temperature among the three or more semiconductor laser elements, and the long-wavelength element 200L may be an element having a longest oscillation wavelength at the room temperature among the three or more semiconductor laser elements.

As described above, since the plurality of semiconductor laser elements 200_1 to 200_N are manufactured by the same manufacturing process, it can be said that the variation in the oscillation wavelength A is within 20 nm. Accordingly, a difference between an oscillation wavelengths λ_{S} and λ_{L} at the room temperature of the short-wavelength element 200S and the long-wavelength element 200L selected from among the semiconductor laser elements 200_1 to 200_N is also 20 nm or less. In addition, as a product standard, the oscillation wavelength may be defined as ±10 nm. Note that, here, the same manufacturing process does not refer to only the same wafer, and it is assumed that the same manufacturing process is performed even for different wafers as long as the wafers are similar laser elements. Statistically, an in-plane variation of a wavelength of the wafer is mostly within 10 nm or less.

At least one of the film thickness, the refractive index, and the number of layers are different between the reflective film 202 on the emitting edge of the short-wavelength element 200S and the reflective film 202 on the emitting edge of the long-wavelength element 200L, and a reflectance (emission end reflectance) RS of the reflective film 202 on the emitting edge of the short-wavelength element 200S and a reflectance RL of the emitting edge reflective film 202 of the long-wavelength element 200L have different wavelength dependencies.

Before describing more specific features of the semiconductor laser device 100, some comparative technologies will be described.

### Comparative Technology 1

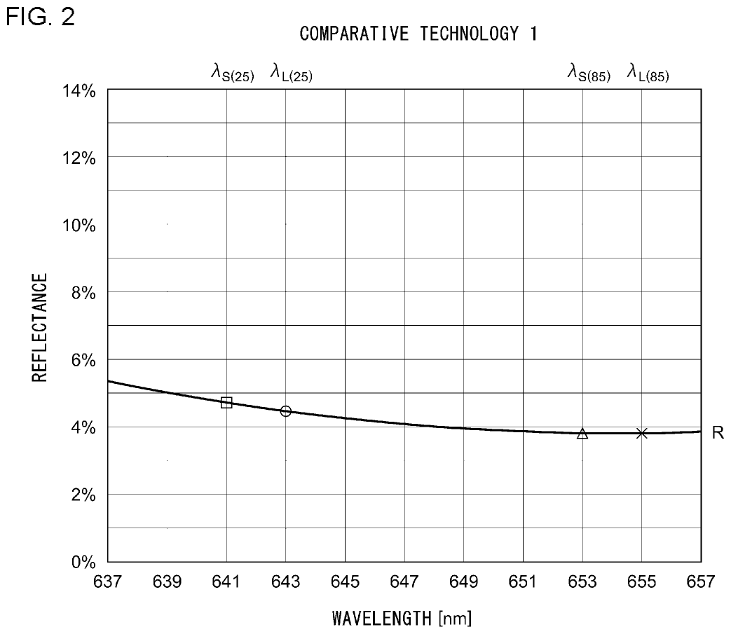

FIG. 2 is a diagram illustrating the wavelength dependencies of the emitting side reflectances R of the short-wavelength element 200S and the long-wavelength element 200L according to Comparative Technology 1.

In Comparative Technology 1, the film thickness, the refractive index, and the number of layers are the same between the reflective film 202 on the emitting edge of the short-wavelength element 200S and the reflective film 202 on the emitting edge of the long-wavelength element 200L, and the reflectances R thereof have the same wavelength dependency. In this example, the reflective films are designed such that the wavelength dependency is reduced.

Examples of a material of the reflective film include oxides or nitrides such as Zr, Si, Nb, Pb, Ti, Ce, Hf, Al, Bi, Cr, In, Nd, Sb, Ta, Y, and V, and other materials such as AlF₃, BaF₂, CeF₂, CaF₂, MgF₂, NdF₃, PbF₂, SrF₂, ZnS, and ZnSe. In addition, the material of the reflective film may be SiO₂, SiN, SiON, AlN, Al₂O₃, AlON, ZrO₂, TiO₂, Nb₂O₅, or Ta₂O₅.

The room temperature is, for example, 25° C. It is assumed that an oscillation wavelength λ_{S(25)} of the short-wavelength element 200S at the room temperature is 641 nm, and an oscillation wavelength λ_{L(25)} of the long-wavelength element 200L at the room temperature (25° C.) is 643 nm.

A high temperature is an upper limit (upper limit of an operating temperature) of a temperature range in which use of the semiconductor laser device 100 is assumed, and is, for example, 85° C. In addition, it is assumed that an oscillation wavelength λ_{S(85)} of the short-wavelength element 200S in the high temperature state (85° C.) is 653 nm, and an oscillation wavelength λ_{L(85)} of the long-wavelength element 200L in the high temperature state (85° C.) is 655 nm. Note that, in a normal red laser, the upper limit of the temperature range is generally 40° C. to 90° C. depending on the design of a product. The upper limit of the operating temperature is determined from a relationship between a light output and a lifespan, and is usually described as an operating temperature range in a product specification or the like. In addition, in a case where the upper limit thereof is not specified, the upper limit thereof is evaluated as the reflectance on the emitting edge in a case where the semiconductor laser element is driven at 90° C. in the present specification. This temperature is usually a temperature measured on a side surface of a package such as a stem, and is substituted by a temperature of a submount, a heat sink, or a package such as a stem disposed in the vicinity of a semiconductor racer chip.

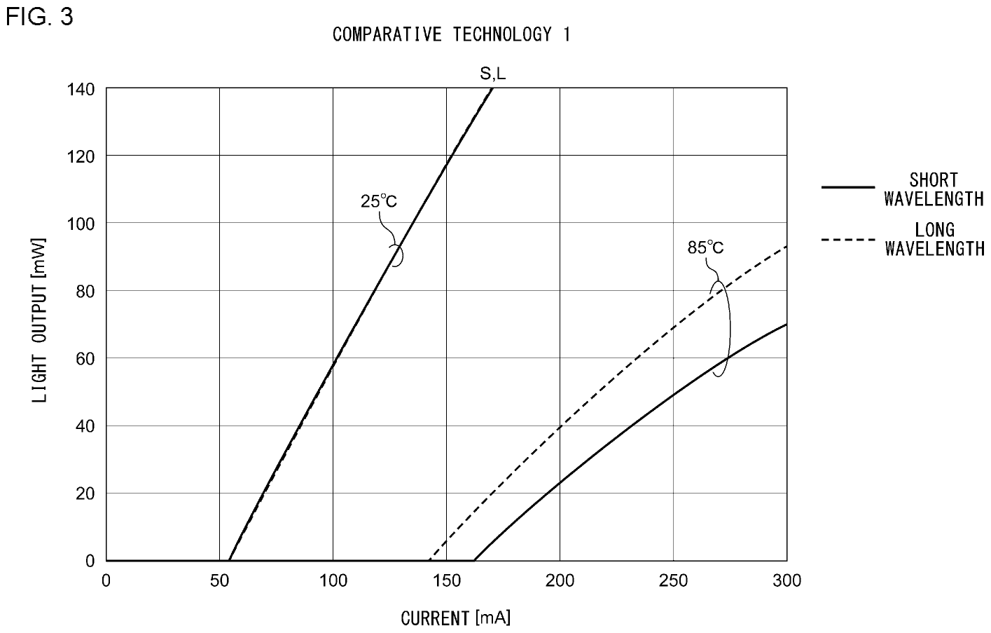

FIG. 3 is a diagram illustrating I-L (current-light output) characteristics of the semiconductor laser device 100 having the reflectance R in FIG. 2. In Comparative Technology 1, the I-L characteristics of the short-wavelength element 200S and the long-wavelength element 200L coincide with each other at 25° C., a threshold current of the short-wavelength element 200S is 55 mA, and a threshold current of the long-wavelength element 200L is 56 mA.

The threshold current of the short-wavelength element 200S increases to 164 mA in the high temperature state (85° C.). The threshold current of the long-wavelength element 200L also increases to 143 mA in the high temperature state (85° C.)

As described above, the semiconductor laser element having a short oscillation wavelength has a large increase in threshold current due to temperature rise, and the semiconductor laser element having a long oscillation wavelength has a smaller increase in threshold current than the semiconductor laser element having a short oscillation wavelength. Thus, in the high temperature state, the difference between the threshold currents of the two laser elements increases (21 mA in the example of FIG. 3), and when a plurality of the semiconductor laser elements are driven with the same current amount, a light output difference between the semiconductor laser elements increases.

### Comparative Technology 2

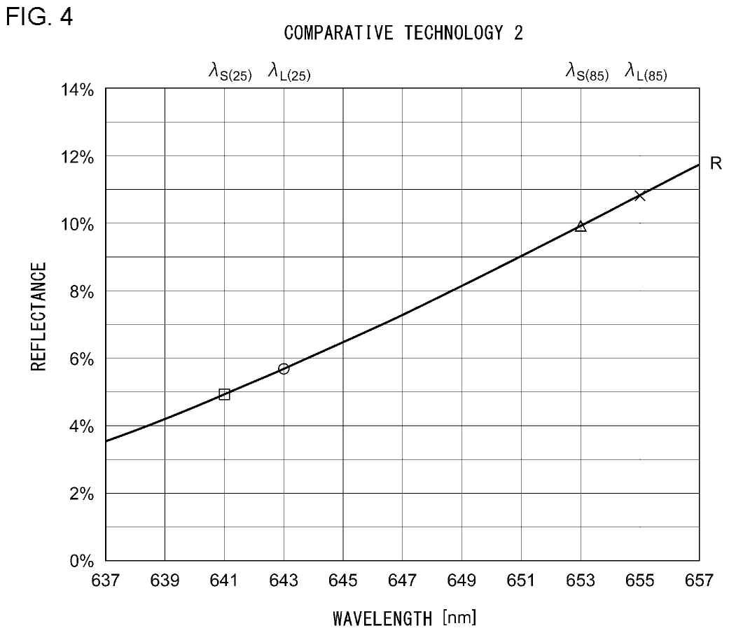

FIG. 4 is a diagram illustrating the wavelength dependencies of the emitting side reflectances R of the short-wavelength element 200S and the long-wavelength element 200L according to Comparative Technology 2.

Similarly to Comparative Technology 1, In Comparative Technology 2, the reflectances R of the short-wavelength element 200S and the long-wavelength element 200L have the same wavelength dependency. In this example, the reflective films are designed such that the longer the wavelength, the higher the reflectance.

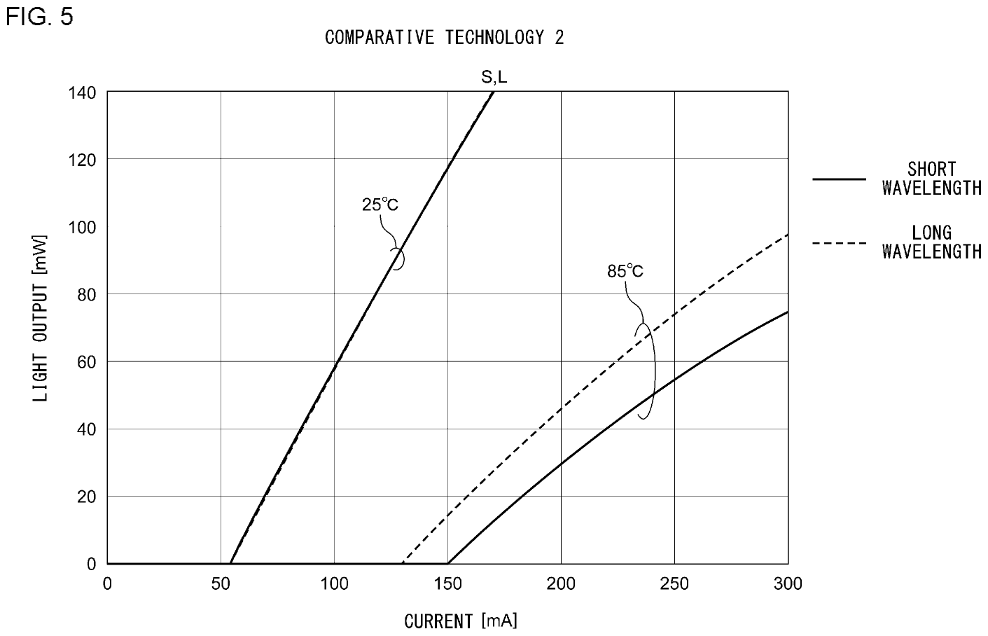

FIG. 5 is a diagram illustrating I-L characteristics of the semiconductor laser device 100 having the reflectance R in FIG. 4.

In Comparative Technology 2, the threshold current of the short-wavelength element 200S in the high temperature state is 151 mA, the threshold current of the long-wavelength element 200L in the high temperature state is 131 mA, and an increase width of the threshold current with the temperature rise can be set to be smaller than in Comparative Technology 1. However, when the threshold currents of the short-wavelength element 200S and the long-wavelength element 200L at 85° C. are compared, a difference therebetween is 151 mA−131 mA=20 mA, and is not almost different from 21 mA of Comparative Technology 1. Accordingly, in Comparative Technology 2, when the short-wavelength element 200S and the long-wavelength element 200L are operated at the same amount of current in the high temperature state, a difference in the light output between the semiconductor laser elements is large.

Advantages of the semiconductor laser device 100 according to the embodiment are clarified by comparison with Comparative Technologies 1 and 2.

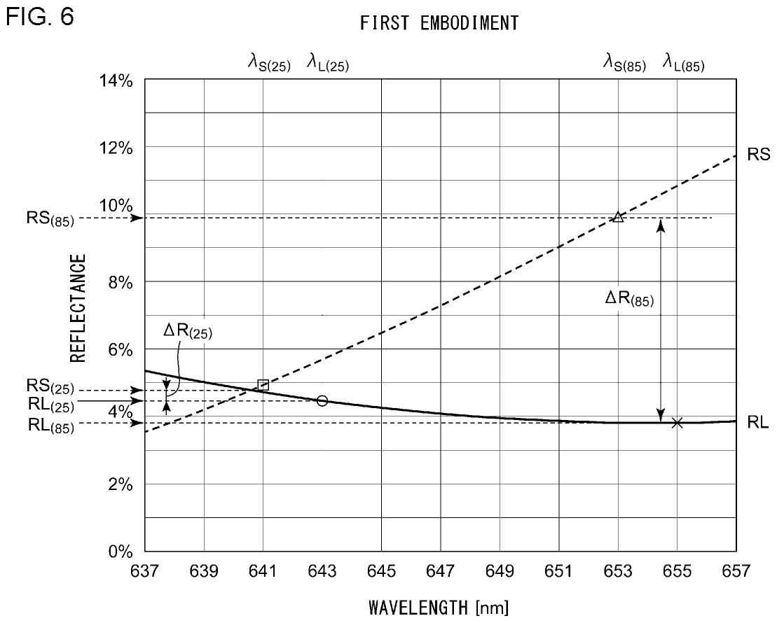

FIG. 6 is a diagram illustrating the wavelength dependencies of the emission end reflectance RS of the short-wavelength element 200S and the emitting side reflectance RL of the long-wavelength element 200L according to the first embodiment.

In the present embodiment, the emission end reflectance RS of the short-wavelength element 200S and the emitting side reflectance RL of the long-wavelength element 200L have several features.

### First Feature

In the present embodiment, the emitting edge reflective film 202 is designed such that an emitting side reflectance RS₍₈₅₎ of the short-wavelength element 200S at the upper limit of the operating temperature (85° C.) is higher than an emitting side reflectance RL₍₈₅₎ of the long-wavelength element 200L at the upper limit of the operating temperature.

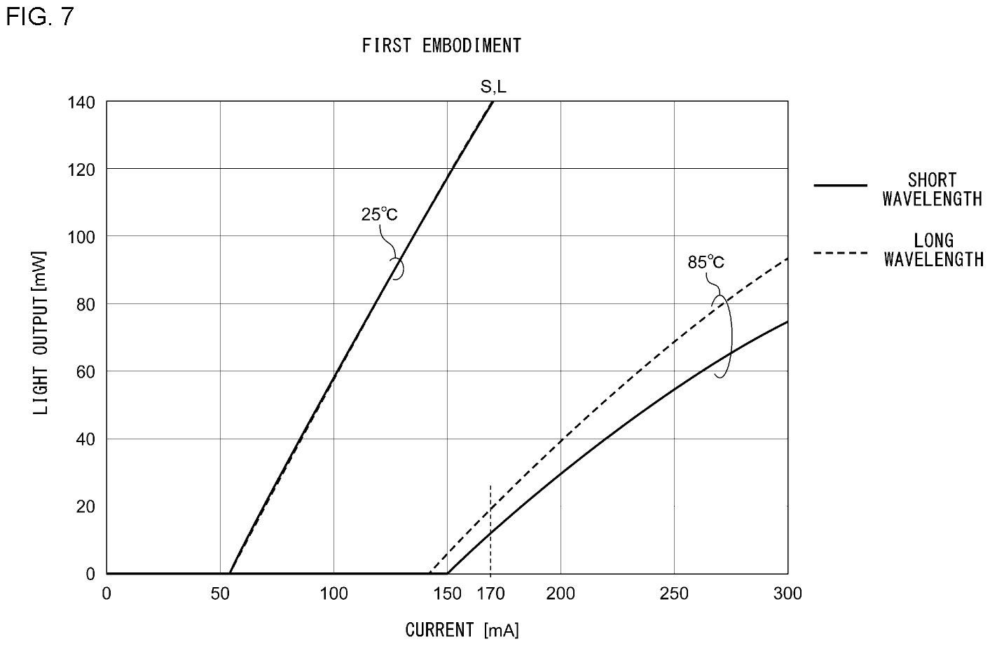

FIG. 7 is a diagram illustrating I-L characteristics of the semiconductor laser element 200 having the reflectance characteristics of FIG. 6.

According to the first feature, a difference between the threshold current of the short-wavelength element 200S at the high temperature (85° C.) and the threshold current of the long-wavelength element 200L at the high temperature can be reduced. Specifically, the threshold current of the short-wavelength element 200S at the high temperature (85° C.) is 151 mA, the threshold current of the long-wavelength element 200L at the high temperature (85° C.) is 143 mA, and the difference between these threshold currents is as small as 8 mA. As a result, in a case where the short-wavelength element 200S and the long-wavelength element 200L are operated with the same amount of current, the variation in the light output can be suppressed.

### Second Feature

Referring to FIG. 6, the emitting side reflectance RL of the long-wavelength element 200L has small wavelength dependency, whereas the emitting side reflectance RS of the short-wavelength element 200S increases as the wavelength increases. In other words, the emitting side reflectance RS₍₂₅₎ of the short-wavelength element 200S at the room temperature is lower than the emitting side reflectance RS₍₈₅₎ at the upper limit of the operating temperature. This is a second feature.

Since the light output is usually higher at the room temperature than at the high temperature, it is important that the COD resistance at the room temperature is high. On the other hand, in the high temperature state, it can be said that reduction in the threshold current is more important in order to suppress the reduction in the light output. In consideration of the balance, it is possible to lower the threshold current at the high temperature while improving the COD resistance by lowering the emitting side reflectance RS₍₂₅₎ at the room temperature and increasing the emitting side reflectance RS₍₈₅₎ at the high temperature.

### Third Feature

Referring to FIG. 6, a difference ΔR₍₂₅₎ (=|RS₍₂₅₎−RL₍₂₅₎|) between the reflectance RS₍₂₅₎ of the short-wavelength element 200S at the room temperature and the emitting side reflectance RL₍₂₅₎ of the long-wavelength element 200L at the room temperature is smaller than a difference ΔR₍₈₅₎ (=|RS₍₈₅₎−RL₍₈₅₎|) between the emitting side reflectance RS₍₈₅₎ of the short-wavelength element 200S at the upper limit of the operating temperature and the emitting side reflectance RL₍₈₅₎ of the long-wavelength element 200L at the upper limit of the operating temperature.

ΔR₍₂₅₎<ΔR₍₈₅₎

Since the difference ΔR₍₂₅₎ in the reflectance on the emitting edge at the room temperature affects the difference in the COD resistance, the difference ΔR₍₂₅₎ in the reflectance on the emitting edge at the room temperature between the semiconductor laser element having the short wavelength and the semiconductor laser element having the long wavelength is desirably as small as possible. In addition, the difference between the threshold current of the semiconductor laser element having a long wavelength and the threshold current of the semiconductor laser element having the short wavelength at the room temperature is smaller than the difference between the threshold current at the high temperature. Thus, the difference ΔR₍₈₅₎ in the emitting side reflectance at the high temperature between the semiconductor laser element having the short wavelength and the semiconductor laser element having the long wavelength may be larger than ΔR₍₂₅₎.

### Fourth Feature

Referring to FIG. 6, the slope of the graph of the short-wavelength element 200S is larger than the slope of the graph of the long-wavelength element 200 L.

The semiconductor laser element having a short wavelength has a larger increase rate of the wavelength with respect to the temperature change than the semiconductor laser element having a long wavelength. Therefore, a slope of the semiconductor laser element having the long wavelength (long-wavelength element 200L) is set to be larger than a slope of the semiconductor laser element having the short wavelength (short-wavelength element 200S), and thus, it is possible to reduce the variation in the threshold current between the semiconductor laser element having the short wavelength and the semiconductor laser element having the long wavelength in a wide temperature range.

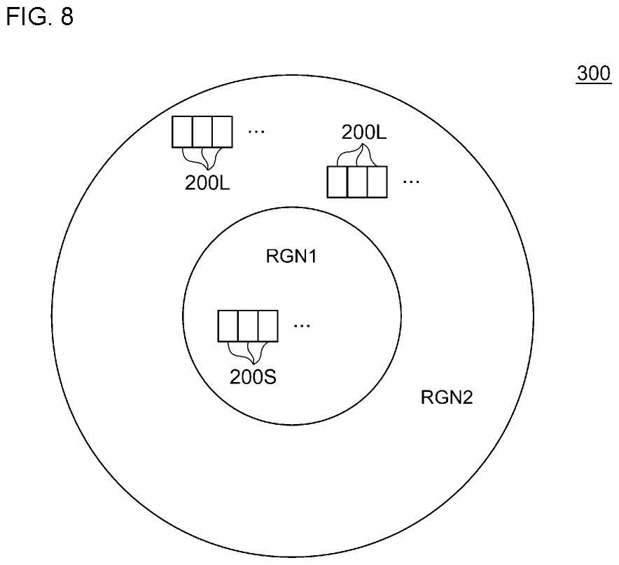

FIG. 8 is a diagram illustrating a wafer 300. A large number of semiconductor laser elements 200 are cut out from the wafer 300. It is assumed that the oscillation wavelength of the semiconductor laser element 200 has a variation corresponding to an in-plane position of the wafer 300 before being cut out. In this example, it is assumed that the wavelength tends to be short in a portion close to a center of the wafer 300 and the wavelength tends to be long in a portion close to an outer periphery. In this case, the wafer 300 can be divided into several regions RGN1, RGN2, . . . in the plane based on a tendency of a distribution of the oscillation wavelength. In the example of FIG. 8, the semiconductor laser element 200 is divided into two regions RGN1 and RNG2, and a reflective film for the short-wavelength element 200S may be formed in the semiconductor laser element cut out from the region RGN1, and a reflective film for the long-wavelength element 200L may be formed in the semiconductor laser element 200 cut out from the region RGN2.

It is possible to predict the distribution of the oscillation wavelength in the regions RGN1 and RGN2 . . . in the wafer plane and the oscillation wavelength for each wafer before forming the reflective film on the emitting edge by a method called photoluminescence. In the present disclosure, it is possible to appropriately select whether to form the reflective film for the short-wavelength element 200S or the reflective film for the long-wavelength element 200L with respect to the region in the wafer or the oscillation wavelength predicted for each wafer. The semiconductor laser device 100 may select the semiconductor laser element 200 from among a plurality of wafers or different wafers.

In the above description, in the semiconductor laser device 100 including N=three or more semiconductor laser elements, the short-wavelength element 200S has the shortest oscillation wavelength at the room temperature, and the long-wavelength element 200L has the longest oscillation wavelength at the room temperature. However, the present invention is not limited thereto.

From another point of view, in the semiconductor laser device 100, it can be said that the above-described relationship between the short-wavelength element 200S and the long-wavelength element 200L is established between any two semiconductor laser elements 200 of the plurality of semiconductor laser elements 200.

### Second Embodiment

The wavelength dependencies of the reflectances of the short-wavelength element 200S and the long-wavelength element 200L in the semiconductor laser device 100 are not limited to that illustrated in FIG. 6.

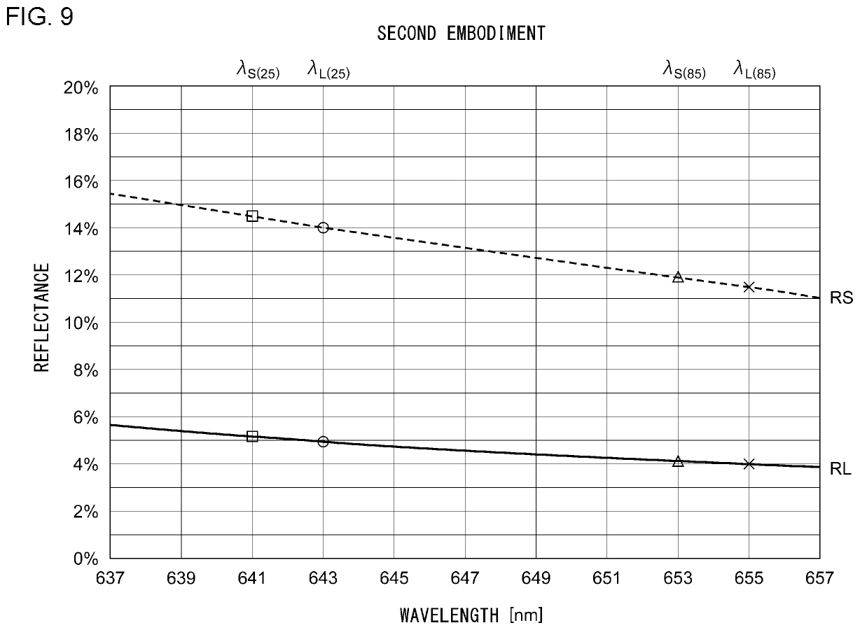

FIG. 9 is a diagram illustrating the wavelength dependencies of the emission end reflectance RS of the short-wavelength element 200S and the emitting side reflectance RL of the long-wavelength element 200L according to a second embodiment. In the second embodiment, the wavelength dependencies of the emission end reflectance RS of the short-wavelength element 200S and the emitting side reflectance RL of the long-wavelength element 200L satisfy only the first feature among the first to third features described in the first embodiment.

RS₍₈₅₎>RL₍₈₅₎

According to the second embodiment, an effect of the first feature can be obtained. That is, the difference in the threshold current between the short-wavelength element 200S and the long-wavelength element 200L in the high temperature state can be reduced, and the variation in the light output can be suppressed in a case where the short- and long-wavelength elements are operated with the same amount of current.

### Modifications

The structure of the semiconductor laser device 100 and the form of the package are not particularly limited.

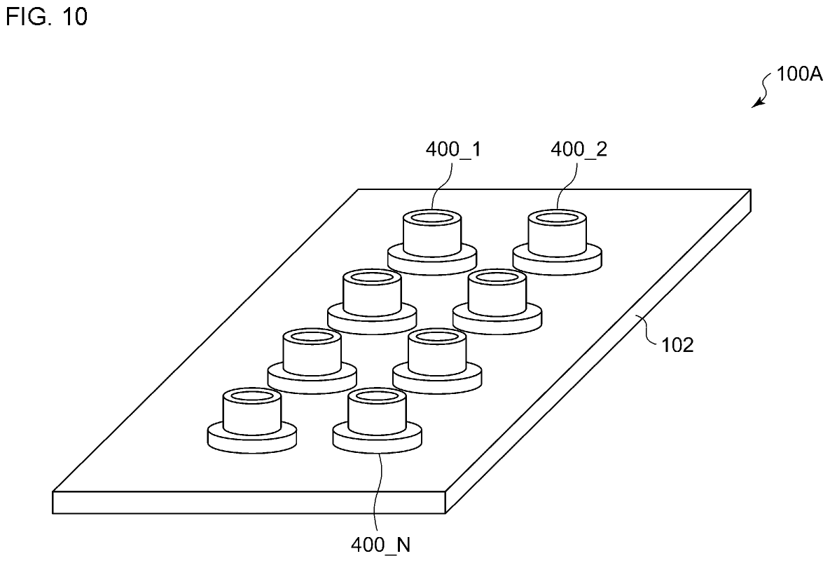

FIG. 10 is a diagram illustrating a semiconductor laser device 100A according to a modification. The semiconductor laser device 100A includes a heat sink 102 and a plurality of semiconductor laser packages 400_1 to 400_N mounted on the heat sink 102.

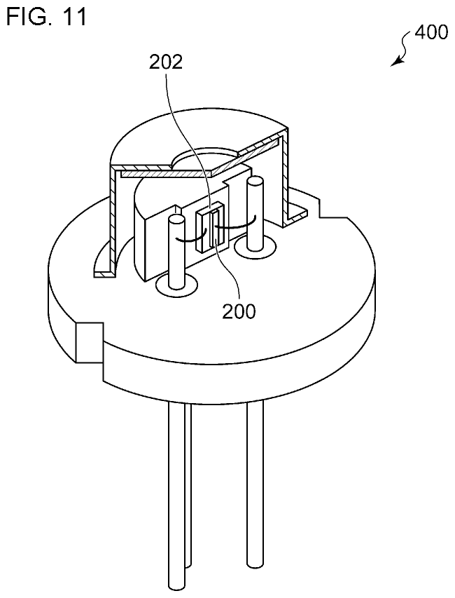

FIG. 11 is a perspective view of the semiconductor laser package 400. The semiconductor laser package 400 is a CAN package, and includes a semiconductor laser element 200. An emitting edge reflective film 202 is formed on an emitting edge of the semiconductor laser element 200.

The technology according to the present disclosure can also be applied to such a semiconductor laser device 100A.

The embodiments merely illustrate the principle and application of the present invention, and many modifications and changes in arrangement are recognized in the embodiments without departing from the spirit of the present invention defined in the claims.

What is claimed is:

1. A semiconductor laser device comprising:
an edge-emitting type first semiconductor laser element having a relatively short oscillation wavelength at a room temperature; and
an edge-emitting type second semiconductor laser element having a relatively long oscillation wavelength at the room temperature,
wherein a difference in the oscillation wavelength at the room temperature between the first semiconductor laser element and the second semiconductor laser element is 20 nm or less,
at least one of a film thickness, a refractive index, and a number of layers is different between a reflective film on an emitting edge of the first semiconductor laser element and a reflective film on an emitting edge of the second semiconductor laser element, and
an emitting side reflectance of the first semiconductor laser element at an operating temperature upper limit is higher than an emitting side reflectance of the second semiconductor laser element at the operating temperature upper limit.

2. The semiconductor laser device according to claim 1, comprising three or more semiconductor laser elements,
wherein the first semiconductor laser element is an element having a shortest oscillation wavelength at the room temperature among the three or more semiconductor laser elements, and
the second semiconductor laser element is an element having a longest oscillation wavelength at the room temperature among the three or more semiconductor laser elements.

3. The semiconductor laser device according to claim 1, wherein the oscillation wavelength is 600 nm to 700 nm.

4. The semiconductor laser device according to claim 1, wherein the emitting side reflectance of the first semiconductor laser element is high as a wavelength is long.

5. The semiconductor laser device according to claim 1, wherein a difference between the emitting side reflectance of the first semiconductor laser element at the room temperature and the emitting side reflectance of the second semiconductor laser element at the room temperature is smaller than a difference between the emitting side reflectance of the first semiconductor laser element at the operating temperature upper limit and the emitting side reflectance of the second semiconductor laser element at the operating temperature upper limit.

6. The semiconductor laser device according to claim 1, wherein, in a graph in which a horizontal axis is plotted as the oscillation wavelength and a vertical axis is plotted as the emitting side reflectance, a slope of the graph of the first semiconductor laser element is larger than a slope of the graph of the second semiconductor laser element.

7. A semiconductor laser device comprising:
a plurality of semiconductor laser elements having different oscillation wavelengths at a room temperature,
wherein at least one of a film thickness, a refractive index, a number of layers is different between reflective films on emitting edges of the plurality of semiconductor laser elements, and
as statistically viewed, an emitting side reflectance of the semiconductor laser element having a short oscillation wavelength at an operating temperature upper limit at the room temperature is higher than an emitting side reflectance of the semiconductor laser element having a long oscillation wavelength at the operating temperature upper limit at the room temperature.
